(19) United States
(12) Patent Application Publication
(10) Pub. No.: US 2025/0142715 A1
(43) Pub. Date: May 1, 2025

(54) SYSTEMS AND METHOD FOR IMPEDANCE MATCHING ACROSS SUBASSEMBLIES

(71) Applicant: Dell Products L.P., Round Rock, TX (US)

(72) Inventors: Sandor Farkas, Round Rock, TX (US); Bhyrav M. Mutnury, Round Rock, TX (US)

(21) Appl. No.: 18/497,420

(22) Filed: Oct. 30, 2023

(51) Int. Cl. H05K 1/02; H05K 1/14; H05K 3/00; H05K 3/36

(52) U.S. Cl. CPC H05K 1/025; H05K 1/14; H05K 3/0005; H05K 3/36

(57) ABSTRACT

In one or more embodiments, a system and method for impedance matching across subassemblies comprises forming a PCB with wider traces, wherein a trace is formed based on a width corresponding to a trace design and a tolerance. The larger width reduces a reflection coefficient to reduce impedance differences. A Surface mount technology (SMT) breakout area may include a thicker microstrip and a conductive silk screen layer may be added to further improve impedance matching without increasing the total height of a PCB.

### BACKGROUND

### Field of the Disclosure

This disclosure relates generally to printed circuit boards (PCBs) in information handling systems and more particularly to impedance matching in multi-board assemblies.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

Embodiments may be generally directed to a method for impedance matching across subassemblies in an information handling system. The method may comprise determining a trace design width for a first trace on a first printed circuit board (PCB) comprising a ground plane, a prepreg layer and a solder mask, determining a tolerance associated with the trace design width of the first trace, determining a trace design width for a second trace on a second printed circuit board (PCB) comprising a ground plane, a prepreg layer and a solder mask, determining a tolerance associated with the trace design width of the second trace, forming the first PCB with a first trace comprising a main portion with a trace width based on the trace design width of the first trace; and a first end with a trace width greater than the trace design width of the first trace; and forming the second PCB with a second trace comprising a main portion with a trace width based on the trace design width of the second trace; and a second end with a trace width greater than the trace design width of the second trace; and joining the first PCB to the second PCB. In some embodiments, the method further comprises forming the first trace with a height greater than a height associated with the first trace design. In some embodiments, forming the first PCB with the first trace comprises forming the first end with a trace width greater than a sum of the trace design width of the first trace and the tolerance associated with the trace design width of the first trace. In some embodiments, the trace width for the first end and the trace width for the second end are formed such that a reflection coefficient is less than 0.9. In some embodiments, the trace width for the first end and the trace width for the second end are formed such that the reflection coefficient is less than 0.7. In some embodiments, the method further comprises forming the first PCB with a conductive silk screen.

Embodiments may be generally directed to a printed circuit board (PCB) comprising a ground plane, a prepreg layer and a solder mask for impedance matching across subassemblies in an information handling system. The PCB may comprise a trace comprising: a main portion with a trace width corresponding to a trace design width; and a first end with a trace width greater than the trace design width. In some embodiments, the trace is formed with a height greater than a height associated with the trace design width. In some embodiments, the first end has a trace width greater than a sum of the trace design width and the tolerance associated with the trace design width of the first trace. In some embodiments, the solder mask is formed with a reduced height relative to a design height. In some embodiments, the PCB further comprises a conductive silk screen adhered to the solder mask.

Embodiments may be generally directed to a system for impedance matching across subassemblies in an information handling system. The system may comprise a first printed circuit board (PCB) comprising a ground plane, a prepreg layer and a solder mask and a second PCB comprising a ground plane, a prepreg layer and a solder mask. The first PCB may comprise a first trace comprising a main portion with a first trace width based on a trace design width of the first trace; and a first end with a trace width greater than the trace design width of the first trace. The second PCB may comprise a second trace comprising a main portion with a second trace width based on the trace design width of the second trace; and a second end with a trace width greater than the trace design width of the second trace.

In some embodiments, the first trace is formed with a height greater than a height associated with the trace design width. In some embodiments, the first end has a trace width greater than a sum of the trace design width of the first trace and a tolerance associated with the trace design width of the first trace. In some embodiments, a solder mask is formed with a reduced height relative to a design height. In some embodiments, the system further comprises a conductive silk screen adhered to the solder mask of the first PCB.

### BRIEF DESCRIPTION OF THE DRAWINGS

For a more complete understanding of the present disclosure and its features/advantages, reference is now made to the following description, taken in conjunction with the accompanying drawings, which are not drawn to scale, and in which:

FIG. 1 depicts a graph illustrating impedance performance for a printed circuit board (PCB) paddle card and trace;

FIG. 2 depicts a side view of an example connector between two PCBs, illustrating potential differences in trace widths due to tolerances;

FIG. 3 depicts a graph illustrating a possible result of differences in trace widths of the connection of FIG. 2;

FIG. 4 depicts a side view of one embodiment of a connector between two PCBs with enlarged trace ends, illustrating potential differences in trace widths due to tolerances;

FIG. 5 depicts a graph illustrating a possible result of differences in trace widths of the connection of FIG. 4;

FIG. 6 depicts a partial perspective view of an example PCB having microstrip traces with small thickness;

FIG. 7 depicts a partial perspective view of one embodiment of a PCB having microstrip traces with thicker thickness;

FIG. 8 depicts a partial perspective view of an example PCB; and

FIG. 9 depicts a partial perspective view of one embodiment of a PCB having a conductive silk screen.

### DETAILED DESCRIPTION

In the following description, details are set forth by way of example to facilitate discussion of the disclosed subject matter. It should be apparent to a person of ordinary skill in the field, however, that the disclosed embodiments are examples and not exhaustive of all possible embodiments.

As used herein, a reference numeral refers to a class or type of entity, and any letter following such reference numeral refers to a specific instance of a particular entity of that class or type. Thus, for example, a hypothetical entity referenced by ‘12A’ may refer to a particular instance of a particular class/type, and the reference ‘12’ may refer to a collection of instances belonging to that particular class/type or any one instance of that class/type in general.

An information handling system (IHS) may include a hardware resource or an aggregate of hardware resources operable to compute, classify, process, transmit, receive, retrieve, originate, switch, store, display, manifest, detect, record, reproduce, handle, and/or utilize various forms of information, intelligence, or data for business, scientific, control, entertainment, or other purposes, according to one or more embodiments. For example, an IHS may be a personal computer, a desktop computer system, a laptop computer system, a server computer system, a mobile device, a tablet computing device, a personal digital assistant (PDA), a consumer electronic device, an electronic music player, an electronic camera, an electronic video player, a wireless access point, a network storage device, or another suitable device and may vary in size, shape, performance, functionality, and price. In one or more embodiments, a portable IHS may include or have a form factor of that of or similar to one or more of a laptop, a notebook, a telephone, a tablet, and a PDA, among others. For example, a portable IHS may be readily carried and/or transported by a user (e.g., a person). In one or more embodiments, components of an IHS may include one or more storage devices, one or more communications ports for communicating with external devices as well as various input and output (I/O) devices, such as a keyboard, a mouse, and a video display, among others. In one or more embodiments, IHS may include one or more buses operable to transmit communication between or among two or more hardware components. In one example, a bus of an IHS may include one or more of a memory bus, a peripheral bus, and a local bus, among others. In another example, a bus of an IHS may include one or more of a Micro Channel Architecture (MCA) bus, an Industry Standard Architecture (ISA) bus, an Enhanced ISA (EISA) bus, a Peripheral Component Interconnect (PCI) bus, HyperTransport (HT) bus, an inter-integrated circuit (I²C) bus, a serial peripheral interface (SPI) bus, a low pin count (LPC) bus, an enhanced serial peripheral interface (eSPI) bus, a universal serial bus (USB), a system management bus (SMBus), and a Video Electronics Standards Association (VESA) local bus, among others.

In one or more embodiments, an IHS may include firmware that controls and/or communicates with one or more hard drives, network circuitry, one or more memory devices, one or more I/O devices, and/or one or more other peripheral devices. For example, firmware may include software embedded in an IHS component utilized to perform tasks. In one or more embodiments, firmware may be stored in non-volatile memory, such as storage that does not lose stored data upon loss of power. In one example, firmware associated with an IHS component may be stored in non-volatile memory that is accessible to one or more IHS components. In another example, firmware associated with an IHS component may be stored in non-volatile memory that may be dedicated to and includes part of that component. For instance, an embedded controller may include firmware that may be stored via non-volatile memory that may be dedicated to and includes part of the embedded controller.

An IHS may include a processor, a volatile memory medium, non-volatile memory media, an I/O subsystem, and a network interface. Volatile memory medium, non-volatile memory media, I/O subsystem, and network interface may be communicatively coupled to processor. In one or more embodiments, one or more of volatile memory medium, non-volatile memory media, I/O subsystem, and network interface may be communicatively coupled to processor via one or more buses, one or more switches, and/or one or more root complexes, among others. In one example, one or more of a volatile memory medium, non-volatile memory media, an I/O subsystem, a and network interface may be communicatively coupled to the processor via one or more PCI-Express (PCIe) root complexes. In another example, one or more of an I/O subsystem and a network interface may be communicatively coupled to processor via one or more PCIe switches.

In one or more embodiments, the term “memory medium” may mean a “storage device”, a “memory”, a “memory device”, a “tangible computer readable storage medium”, and/or a “computer-readable medium”. For example, computer-readable media may include, without limitation, storage media such as a direct access storage device (e.g., a hard disk drive, a floppy disk, etc.), a sequential access storage device (e.g., a tape disk drive), a compact disk (CD), a CD-ROM, a digital versatile disc (DVD), a random access memory (RAM), a read-only memory (ROM), a one-time programmable (OTP) memory, an electrically erasable programmable read-only memory (EEPROM), and/or a flash memory, a solid state drive (SSD), or any combination of the foregoing, among others.

In one or more embodiments, one or more protocols may be utilized in transferring data to and/or from a memory medium. For example, the one or more protocols may include one or more of small computer system interface (SCSI), Serial Attached SCSI (SAS) or another transport that operates with the SCSI protocol, advanced technology attachment (ATA), serial ATA (SATA), a USB interface, an Institute of Electrical and Electronics Engineers (IEEE) 1394 interface, a Thunderbolt interface, an advanced technology attachment packet interface (ATAPI), serial storage architecture (SSA), integrated drive electronics (IDE), or any combination thereof, among others.

A volatile memory medium may include volatile storage such as, for example, RAM, DRAM (dynamic RAM), EDO RAM (extended data out RAM), SRAM (static RAM), etc. One or more of non-volatile memory media may include nonvolatile storage such as, for example, a read only memory (ROM), a programmable ROM (PROM), an erasable PROM (EPROM), an electrically erasable PROM, NVRAM (non-volatile RAM), ferroelectric RAM (FRAM), a magnetic medium (e.g., a hard drive, a floppy disk, a magnetic tape, etc.), optical storage (e.g., a CD, a DVD, a BLU-RAY disc, etc.), flash memory, a SSD, etc. In one or more embodiments, a memory medium can include one or more volatile storages and/or one or more nonvolatile storages.

In one or more embodiments, a network interface may be utilized in communicating with one or more networks and/or one or more other information handling systems. In one example, network interface may enable an IHS to communicate via a network utilizing a suitable transmission protocol and/or standard. In a second example, a network interface may be coupled to a wired network. In a third example, a network interface may be coupled to an optical network. In another example, a network interface may be coupled to a wireless network. In one instance, the wireless network may include a cellular telephone network. In a second instance, the wireless network may include a satellite telephone network. In another instance, the wireless network may include a wireless Ethernet network (e.g., a Wi-Fi network, an IEEE 802.11 network, etc.).

In one or more embodiments, a network interface may be communicatively coupled via a network to a network storage resource. For example, the network may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, an Internet or another appropriate architecture or system that facilitates the communication of signals, data and/or messages (generally referred to as data). For instance, the network may transmit data utilizing a desired storage and/or communication protocol, including one or more of Fibre Channel, Frame Relay, Asynchronous Transfer Mode (ATM), Internet protocol (IP), other packet-based protocol, Internet SCSI (iSCSI), or any combination thereof, among others.

In one or more embodiments, a processor may execute processor instructions in implementing at least a portion of one or more systems, at least a portion of one or more flowcharts, at least a portion of one or more methods, and/or at least a portion of one or more processes. In one example, a processor may execute processor instructions from one or more memory media in implementing at least a portion of one or more systems, at least a portion of one or more flowcharts, at least a portion of one or more methods, and/or at least a portion of one or more processes. In another example, a processor may execute processor instructions via a network interface in implementing at least a portion of one or more systems, at least a portion of one or more flowcharts, at least a portion of one or more methods, and/or at least a portion of one or more processes.

In one or more embodiments, a processor may include one or more of a system, a device, and an apparatus operable to interpret and/or execute program instructions and/or process data, among others, and may include one or more of a microprocessor, a microcontroller, a digital signal processor (DSP), an application specific integrated circuit (ASIC), and another digital or analog circuitry configured to interpret and/or execute program instructions and/or process data, among others. In one example, a processor may interpret and/or execute program instructions and/or process data stored locally (e.g., via memory media and/or another component of an IHS). In another example, a processor may interpret and/or execute program instructions and/or process data stored remotely (e.g., via a network storage resource).

In one or more embodiments, an I/O subsystem may represent a variety of communication interfaces, graphics interfaces, video interfaces, user input interfaces, and/or peripheral interfaces, among others. For example, an I/O subsystem may include one or more of a touch panel and a display adapter, among others. For instance, a touch panel may include circuitry that enables touch functionality in conjunction with a display that is driven by a display adapter.

A non-volatile memory medium may include an operating system (OS) and applications (APPs). In one or more embodiments, one or more of an OS and APPs may include processor instructions executable by a processor. In one example, a processor may execute processor instructions of one or more of OS and APPs via a non-volatile memory medium. In another example, one or more portions of the processor instructions of one or more of an OS and APPs may be transferred to a volatile memory medium and a processor may execute the one or more portions of the processor instructions.

Non-volatile memory medium may include information handling system firmware (IHSFW). In one or more embodiments, IHSFW may include processor instructions executable by a processor. For example, IHSFW may include one or more structures and/or one or more functionalities of and/or compliant with one or more of a basic input/output system (BIOS), an Extensible Firmware Interface (EFI), a Unified Extensible Firmware Interface (UEFI), and an Advanced Configuration and Power Interface (ACPI), among others. In one instance, a processor may execute processor instructions of IHSFW via non-volatile memory medium. In another instance, one or more portions of the processor instructions of IHSFW may be transferred to volatile memory medium, and processor may execute the one or more portions of the processor instructions of IHSFW via volatile memory medium.

PCB traces are manufactured with tolerances. A trace design may specify a trace width and a tolerance for the trace width. For example, a trace design may specify a trace design width of 1 millimeter and a tolerance of 0.1 millimeter, wherein a trace may be formed with an actual trace width of 1 millimeter+/−0.1 millimeters and still be within tolerances. An impedance for the trace may depend on the actual trace width. Thus, if a trace is formed with an actual trace width of 1 millimeter, the trace will have an impedance (Z). However, if the actual trace width is 1.1 millimeters (due to a tolerance of +0.1 millimeters), the impedance may be less (e.g., Z−10% due to a 10% increase in trace width). Similarly, if the actual trace width is 0.9 millimeters (due to a tolerance of −0.1 millimeters), the impedance may be more (e.g., Z+10% due to a 10% decrease in trace width). Impedance (Z) tolerance can be up to +/−10% board-to-board. This can lead to impedance discontinuities in multi-board assemblies. In multi-board assemblies, there are, for example, vias, connector, cables, and hot-bar pads. These result in impedance discontinuities and these impedance discontinuities get aggravated by the impedance variations of the board.

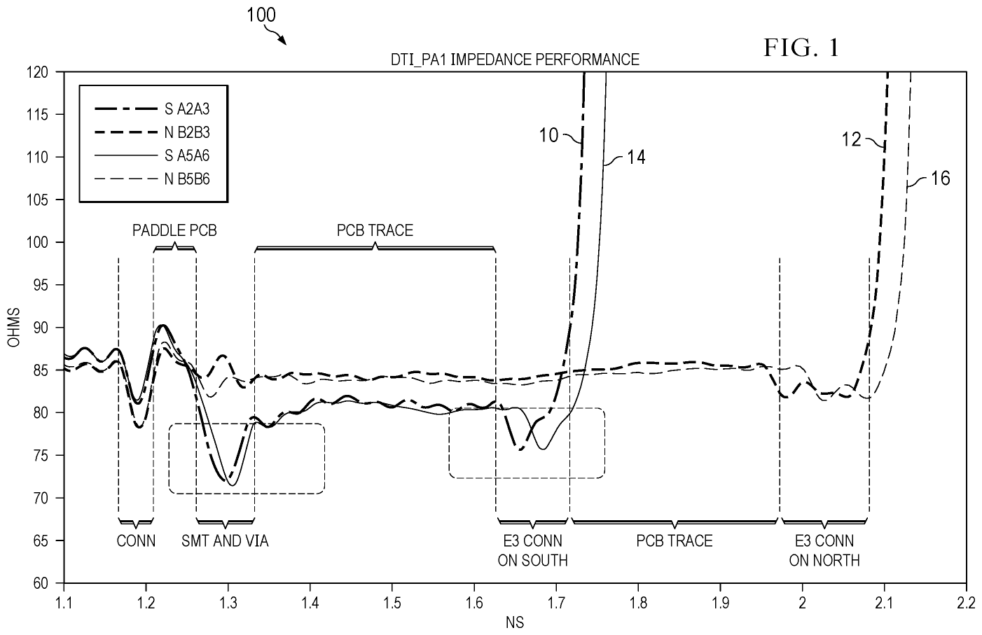

FIG. 1 depicts a graph illustrating impedance performance relative to time in nanoseconds (NS), which may also be relative to distance as a signal travels along traces between printed circuit boards (PCBs). As a signal travels between boards in an information handling system, ideally the signal strength remains constant. For example, lines 12 and 16 are generally flat between 1.3 and 1.6 nanoseconds. However, as depicted in FIG. 1, impedance mismatches affect the signal. For example, when a signal reaches an end of a trace (e.g., illustrated by lines 10 and 14 around 1.7 nanoseconds and lines 12 and 16 around 2.1 nanoseconds), impedance increase significantly due to the open end. If the impedance mismatch is smaller, (e.g., at E3 connector on north), this may indicate the trace width difference is smaller between two traces as compared to larger peaks that may illustrate larger mismatches (e.g., lines 10 and 14 between 1.2 and 1.3 nanoseconds)

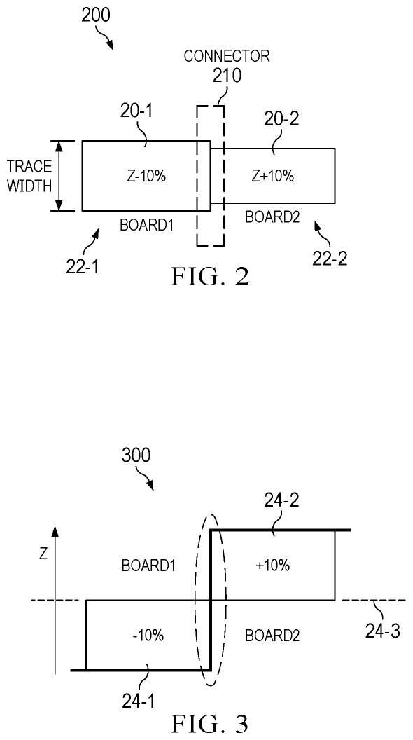

FIG. 2 depicts a top view of a connection 200 between two PCBs 22 comprising two traces 20 and a connector 210, wherein a first trace 20-1 on a first board 22-1 is connected to a second trace 20-2 on a second board 22-2. First trace 20-1 has a first trace width based on a trace design and second trace 20-2 has a second trace width based on a trace design. As depicted in FIG. 1, due to tolerances in trace widths, first trace 20-1 may be formed wider than a trace design width and second trace 20-2 may be formed narrower than a trace design width. First trace 20-1 may have a first impedance (e.g., Z−10%) less than an impedance (Z) for a trace formed with the design trace width. Second trace 20-2 may have a second impedance (e.g., Z+10%) greater than the impedance (Z) for a trace formed with the design trace width.

FIG. 3 depicts a graph of impedances 24 for traces 20-1 and 20-2, illustrating a worst-case reflection coefficient resulting from the difference between first impedance 24-1 of first trace 20-1 being Z−10% and second impedance 24-2 of second trace 20-2 being Z+10% (an impedance Z associated with a trace design may be represented by line 24-3). The worst-case reflection coefficient may be calculated as (1+t−(1−t))/(1+t+1−t)=t. Referring to FIG. 2, the reflection coefficient may be 0.1.

Embodiments may reduce impedance mismatches between PCBs 22 by increasing the trace widths 20 near the ends of traces 20 such that impedance decreases. For example, referring to the discussion above, if the trace design width is 1 millimeter and the trace width tolerance is +/−0.1 millimeters, by increasing the actual trace width to be greater than trace design width, the impedance will decrease, and reflection coefficients will also decrease.

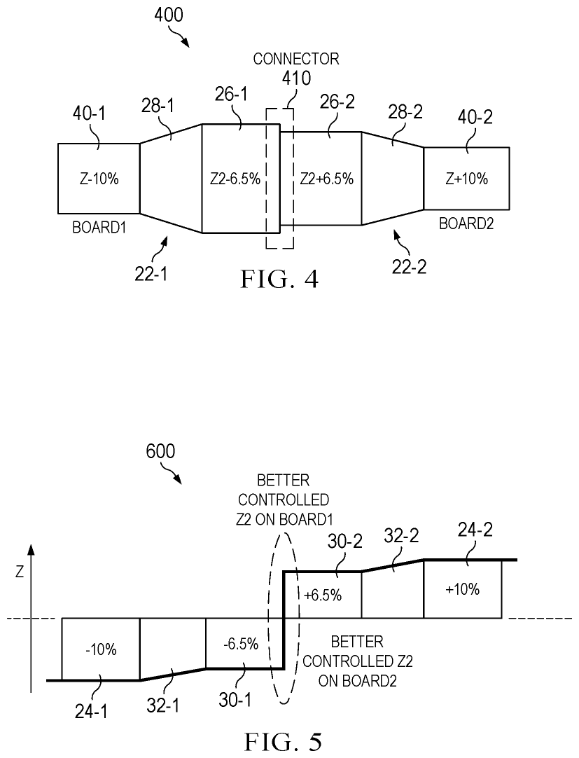

FIG. 4 depicts a top view of one embodiment of a connection 400 between two PCBs 22 comprising two traces 40-1 and 40-2 and connector 410, wherein first trace 40-1 on first board 22-1 is connected to a second trace 40-2 on a second board 22-2. First trace 40-1 may generally have a first trace width but transition (e.g., using transition section 28-1) to a wider trace width at first trace end 26-1 near connector 410. Similarly, second trace 40-2 may have a second trace width but transition (e.g., using transition section 28-2) to a wider trace width at second trace end 26-2 near connector 410. Similar to the description in FIG. 2, first trace 40-1 may be formed wider than a trace design width and second trace 40-2 may be formed narrower than a trace design width.

FIG. 5 depicts a graph illustrating the change in impedances between the two PCBs of FIG. 4, wherein impedance 24-1 corresponds to first trace 40-1, impedance 30-1 corresponds to first trace end 26-1 and impedance 32-1 corresponds to transition section 28-1 on board 22-1, and impedance 24-2 corresponds to second trace 40-2, impedance 30-2 corresponds to second trace end 26-2 and impedance 32-2 corresponds to transition section 28-2 on board 22-2. Forming first trace end 26-1 and second trace end 26-2 with larger trace widths may result in lower impedance differentials. For example, forming first trace end 26-1 and second trace end 26-2 with larger ends 26 but maintaining the same design tolerances (e.g., +/−0.1 millimeters) may reduce the difference between a first impedance (e.g., impedance 24-1 corresponding to first trace 40-1) and a second impedance (e.g., impedance 24-2 corresponding to second trace 40-2). As depicted in FIG. 5, a difference between the first impedance 30-1 and the impedance 24-1 corresponding to the trace design width may be decreased (e.g., from Z−10% to Z−6.5%) using transition section 28-1 and a difference between the second impedance 30-2 and the impedance 24-2 corresponding to the trace design width may be decreased (e.g., from Z+10% to Z+6.5%) using transition section 28-2. A decrease in a difference between an impedance and the impedance corresponding to the trace design width reduces unwanted reflection. The worst-case reflection coefficient may be calculated as (1+kt−(1−kt))/(1+kt+1−kt)=kt. Referring to FIG. 4, the reflection coefficient may be 0.65, resulting in a 35% Z match improvement.

In addition to wider ends for reduced impedance mismatches, embodiments may utilize thicker conductors that have less impedance sensitivity to geometric tolerances.

FIG. 6 depicts an end view of an example design of PCB 600 comprising ground plane 602, prepreg layer 604, solder mask 606 and microstrip traces 608, wherein each of ground plane 602, prepreg layer 604, solder mask 606 and microstrip traces 608 may have a design height and microstrip traces 608 may further have a design width.

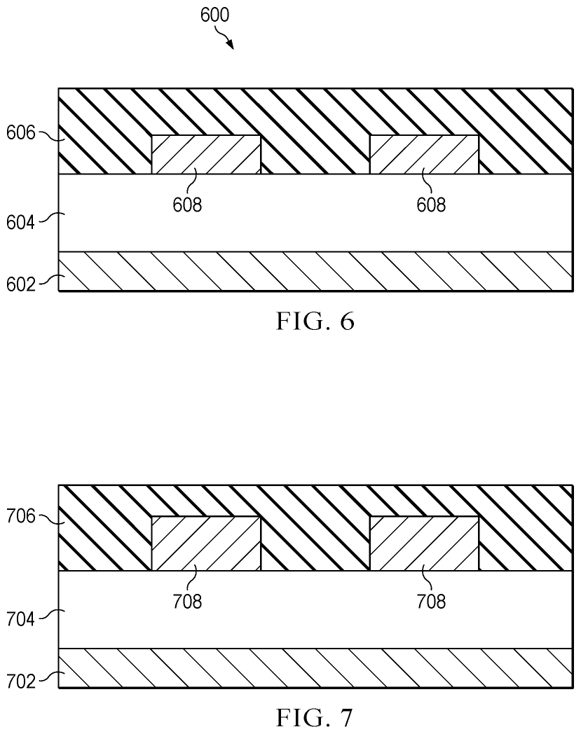

FIG. 7 depicts an end view of one embodiment of a PCB 700 comprising ground plane 702, prepreg layer 704, solder mask 706 and microstrip traces 708 in which each of ground plane 702, prepreg layer 704, solder mask 706 and microstrip traces 708 may have a design height but microstrip traces 708 are formed thicker than traces 708 depicted in FIG. 6. Heavier plating may be applied to outer layers such that a SMT connector breakout area may be formed as a thicker microstrip trace 708. Advantageously, forming thicker traces 708 may increase the coupling between traces 708 to further improve impedance stability. Notably, an actual height of PCB 700 may be equal to a height of a design height associated with PCB 600.

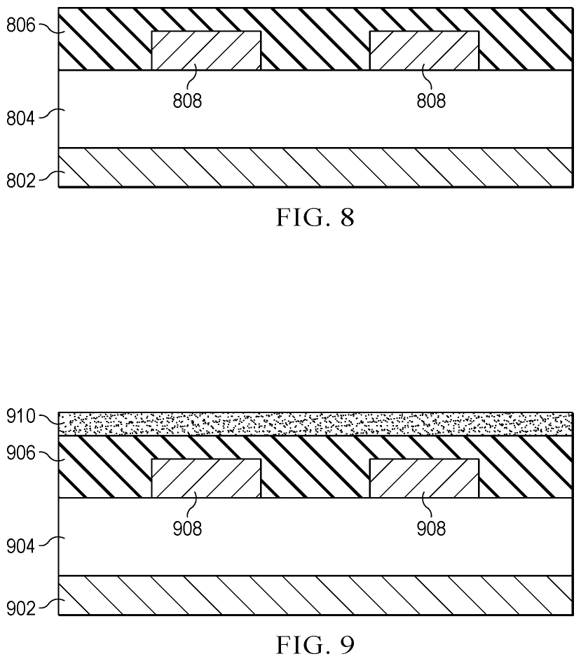

FIG. 8 depicts an end view of one example design of PCB 800 comprising ground plane 802, prepreg layer 804, solder mask 806 and microstrip traces 808, wherein each of ground plane 802, prepreg layer 804, solder mask 806 and microstrip traces 808 may have a design height and a design width and PCB 800 may have a total height.

FIG. 9 depicts an end view of one embodiment of a PCB 900 comprising ground plane 902, prepreg layer 904, solder mask 906 and microstrip traces 908 and further comprising conductive silk screen layer 910 applied to solder mask 906, wherein one or more of ground plane 902, prepreg layer 904 and solder mask 906 may be formed thinner to accommodate silk screen layer 910 without increasing the total height of PCB 900. Conductive silk screen layer 910 may be printed in a SMT connector breakout area, resulting in lower impedance and may create a strip-like geometry having a decreased sensitivity to dielectric height tolerances below traces 908. Notably, a height of PCB 900 may be equal to a height of PCB 800 due to a reduced thickness of solder mask 906.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for impedance matching across subassemblies in an information handling system, the method comprising:
determining a trace design width for a first trace on a first printed circuit board (PCB) comprising a ground plane, a prepreg layer and a solder mask;
determining a tolerance associated with the trace design width of the first trace;
determining a trace design width for a second trace on a second printed circuit board (PCB) comprising a ground plane, a prepreg layer and a solder mask;
determining a tolerance associated with the trace design width of the second trace;
forming the first PCB with a first trace comprising:
a main portion with a trace width based on the trace design width of the first trace; and
a first end with a trace width greater than the trace design width of the first trace; and
forming the second PCB with a second trace comprising:
a main portion with a trace width based on the trace design width of the second trace; and
a second end with a trace width greater than the trace design width of the second trace; and
joining the first PCB to the second PCB.

2. The method of claim 1, further comprising forming the first trace with a height greater than a height associated with the first trace design.

3. The method of claim 1, wherein forming the first PCB with the first trace comprises forming the first end with a trace width greater than a sum of the trace design width of the first trace and the tolerance associated with the trace design width of the first trace.

4. The method of claim 3, wherein the trace width for the first end and the trace width for the second end are formed such that a reflection coefficient is less than 0.9.

5. The method of claim 4, wherein the trace width for the first end and the trace width for the second end are formed such that the reflection coefficient is less than 0.7.

6. The method of claim 1, further comprising forming the first PCB with a conductive silk screen.

7. A printed circuit board (PCB) comprising a ground plane, a prepreg layer and a solder mask for impedance matching across subassemblies in an information handling system, the PCB comprising:
a trace comprising:
a main portion with a trace width corresponding to a trace design width; and
a first end with a trace width greater than the trace design width.

8. The PCB of claim 7, wherein the trace is formed with a height greater than a height associated with the trace design width.

9. The PCB of claim 8, wherein the first end has a trace width greater than a sum of the trace design width and the tolerance associated with the trace design width of the first trace.

10. The PCB of claim 9, wherein the solder mask is formed with a reduced height relative to a design height.

11. The PCB of claim 7, further comprising a conductive silk screen adhered to the solder mask.

12. A system for impedance matching across subassemblies in an information handling system, the system comprising:
a first printed circuit board (PCB) comprising a ground plane, a prepreg layer and a solder mask, the first PCB comprising:
a first trace comprising:
a main portion with a first trace width based on a trace design width of the first trace; and
a first end with a trace width greater than the trace design width of the first trace; and
a second PCB comprising a ground plane, a prepreg layer and a solder mask, the second PCB comprising:
a second trace comprising:
a main portion with a second trace width based on the trace design width of the second trace; and
a second end with a trace width greater than the trace design width of the second trace.

13. The system of claim 12, wherein the first trace is formed with a height greater than a height associated with the trace design width.

14. The system of claim 13, wherein the first end has a trace width greater than a sum of the trace design width of the first trace and a tolerance associated with the trace design width of the first trace.

15. The system of claim 14, wherein a solder mask is formed with a reduced height relative to a design height.

16. The system of claim 12, further comprising a conductive silk screen adhered to the solder mask of the first PCB.
